(19) United States
(12) Patent Application Publication
(10) Pub. No.: US 2025/0140696 A1
(43) Pub. Date: May 1, 2025

(54) INTERCONNECTION STRUCTURE AND MANUFACTURING METHOD THEREOF

(71) Applicant: Taiwan Semiconductor Manufacturing Company, Ltd., Hsinchu (TW)

(72) Inventors: Han-Tang HUNG, Hsinchu (TW); Tsu-Chun KUO, Hsinchu (TW); Shin-Yi YANG, Hsinchu (TW)

(73) Assignee: Taiwan Semiconductor Manufacturing Company, Ltd., Hsinchu (TW)

(21) Appl. No.: 18/385,435

(22) Filed: Oct. 31, 2023

(51) Int. Cl. H01L 23/532; H01L 21/768; H01L 23/522; H01L 23/528

(52) U.S. Cl. CPC H01L 23/53238; H01L 21/76807; H01L 21/76843; H01L 23/5226; H01L 23/5283; H01L 23/53214; H01L 23/53219; H01L 23/53242; H01L 23/53247; H01L 23/53257; H01L 23/53261

(57) ABSTRACT

An interconnection structure includes a first dielectric layer, a second dielectric layer, a first conductive feature, and a second conductive feature. The second dielectric layer is disposed on one side of the first dielectric layer. The first conductive feature is embedded in the first dielectric layer or the second dielectric layer, the second conductive feature is embedded in the first dielectric layer or the second dielectric layer, wherein the first The conductive feature includes a first conductive material, the second conductive feature includes a second conductive material and a barrier layer, the first conductive material is different from the second conductive material. The first conductive material does not contain copper, and the second conductive material contains copper.

### BACKGROUND

As the semiconductor industry introduces new generations of integrated circuits (IC) having higher performance and more functionality, the density of the elements forming the ICs increases, while the dimensions, sizes and spacing between components or elements are reduced. The semiconductor industry continues to improve the integration density of various electronic components (e.g., transistors, diodes, resistors, capacitors, etc.) by continual reductions in minimum feature size, which allow more components to be integrated into a given area.

In addition, the traditional interconnection structure is formed in the dielectric layer through copper damascene process, however, as the copper damascene interconnect keeps scaling aggressively in the back-end-of-the-line (BEOL), the resistivity of copper increases dramatically due to the electron scattering and is proportional to lower copper volume.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B illustrate a flow chart of an exemplary manufacturing method of an interconnection structure according to an embodiment of the present disclosure.

FIGS. 2A to 2C illustrate a flow chart of an exemplary manufacturing method of an interconnection structure according to another embodiment of the present disclosure.

FIG. 3 is a schematic diagram of an interconnection structure according to another embodiment of the present disclosure.

FIGS. 4A and 4B illustrate a flow chart of an exemplary manufacturing method of an interconnection structure according to another embodiment of the present disclosure.

FIGS. 5A to 5C illustrate a flow chart of an exemplary manufacturing method of an interconnection structure according to another embodiment of the present disclosure.

FIGS. 6A and 6B illustrate a flow chart of an exemplary manufacturing method of an interconnection structure according to an embodiment of the present disclosure.

FIGS. 7A to 7C illustrate a flow chart of an exemplary manufacturing method of an interconnection structure according to another embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

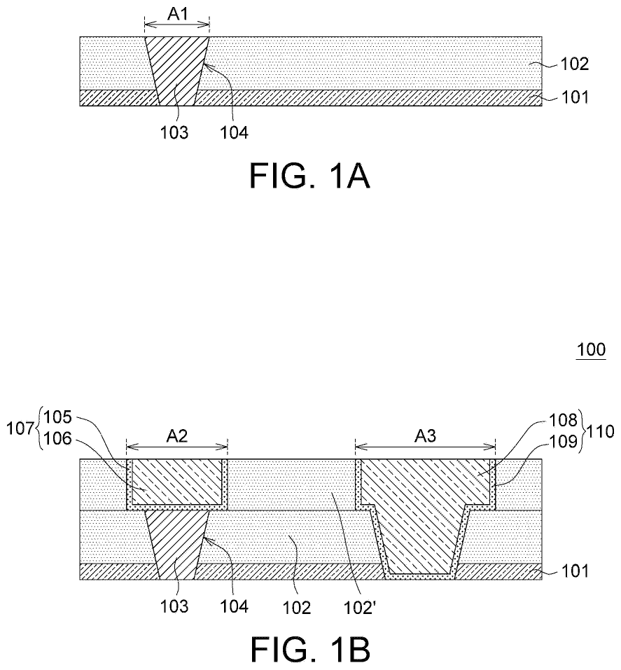

Referring to FIGS. 1A and 1B, a flow chart of an exemplary manufacturing method of the interconnection structure 100 according to an embodiment of the present disclosure is shown. The interconnection structure 100 may be formed on various devices of a semiconductor structure. For example, the interconnection structure 100 may be formed over one or more devices, such as transistors, diodes, image sensors, resistors, capacitors, inductors, memory cells, the above combinations, and/or other suitable devices. In some embodiments, the interconnection structure 100 may be formed over a transistor, such as a nanostructured field-effect-transistor having a plurality of channels surrounded by a gate electrode layer.

It can be understood that the interconnection structure 100 is not limited to being directly formed on the semiconductor device (not shown). Other structures (e.g., middle-end-of-the-line (MEOL) structures) may be formed between the interconnection structure 100 and the semiconductor device. Therefore, the interlayer dielectric layers of the interconnection structure 100 may be two layers, three layers, or more.

Referring to FIG. 1B, the interconnection structure 100 may include a first dielectric layer 102, a second dielectric layer 102′, a first conductive feature 104 and a second conductive feature 107. The first conductive feature 104 is embedded in the first dielectric layer 102, and the second dielectric layer 102′ is disposed on one side of the first dielectric layer 102. The second conductive feature 107 is embedded in the second dielectric layer 102′, and the second conductive feature 107 is electrically connected to the first conductive feature 104. The first conductive feature 104 includes a first conductive material 103, the second conductive feature 107 includes a second conductive material 106 and a barrier layer 105, and the first conductive material 103 is different from the second conductive material 106. The following description will be based on the manufacturing method of the interconnection structure 100 shown in FIGS. 1A and 1B.

First, in FIG. 1A, a first dielectric layer 102 is formed on an etch stop layer 111. Next, the first dielectric layer 102 is patterned to form a predetermined pattern (such as a blind via), and the first conductive material 103 is filled in the blind via to form a first conductive feature 104. The first conductive feature 104 is embedded in the first dielectric layer 102, and the first conductive feature 104 is planarized by removing excess portion of the first conductive material 103 and exposing the top surface of the first conductive feature 104 and the top surface of the first dielectric layer 102. In one embodiment, the top surface of the first conductive feature 104 and the top surface of the first dielectric layer 102 are substantially coplanar.

Next, in FIG. 1B, a second dielectric layer 102′ is formed on top of the first dielectric layer 102. Next, the second dielectric layer 102′ is patterned to form a predetermined pattern (such as a trench), and the barrier layer 105 and the second conductive material 106 are filled in the trench to form a second conductive feature 107. A second conductive feature 107 is embedded in the second dielectric layer 102′, and the second conductive feature 107 overlaps and is electrically connected to the first conductive feature 104. In one embodiment, a planarization process is performed on the second conductive feature 107 to remove excess portions of the barrier layer 105 and the second conductive material 106, and expose the top surface of the second conductive feature 107 and the top surface of the second dielectric layer 102′, such that the top surface of second conductive feature 107 and the top surface of second dielectric layer 102′ are substantially coplanar.

In one embodiment, the first dielectric layer 102 and the second dielectric layer 102′ can be formed by physical vapor deposition (PVD), chemical vapor deposition (CVD), atomic layer deposition (ALD), spin coating or other suitable processes. The first dielectric layer 102 and the second dielectric layer 102′ may include amorphous SiOx, SiOxCyHz, SiOxCy, SiCx, SiNx or related low-k value materials. The k value of the first dielectric layer 102 and the second dielectric layer 102′ may be between 1.0 and 5.0. In some embodiments, the first dielectric layer 102 and the second dielectric layer 102′ can be made of SiOx, SiOxCyHz, SiOxCy, SiCx, SiNx or related low-k materials with ordered pores. The term “ordered pores” as used herein refers to a defined arrangement of air-filled pores or air gaps formed within a dielectric material. The first dielectric layer 102 and the second dielectric layer 102′ having ordered pores have the characteristics of low dielectric constant and high mechanical strength.

In one embodiment, the first conductive material 103 may include cobalt (Co), ruthenium (Ru), molybdenum (Mo), chromium (Cr), tungsten (W), manganese (Mn), rhodium (Rh), iridium (Ir), nickel (Ni), palladium (Pd), platinum (Pt), silver (Ag), gold (Au), aluminum (Al), alloys of the above, or other suitable materials. The first conductive material 103 may be metal alloys such as CuAl, NiAl, RuAl, VNi, VPt, AlSc, ternary alloys, quaternary alloys or the combination of the metals above with different composition. The first conductive material 103 can be at a temperature of 100 degrees Celsius to 1000 degrees Celsius temperature by physical vapor deposition (PVD), chemical vapor deposition (CVD), atomic layer deposition (ALD), electroless deposition (ELD), electrochemical plating (ECP), MBE (molecular beam epitaxy), IBD (ion beam deposition) or other suitable processes to form. Different annealing process (RTA, laser, furnace) can be applied to improve the crystallinity and reduce resistance of alloys of the first conductive material or promotes the intermetallic compounds formation. The annealing temperature can be between 100° C. and 1400° C.

In some embodiments, the second conductive material 106 may include copper or a copper alloy. The second conductive material 106 is formed, for example, by chemical vapor deposition (CVD), atomic layer deposition (ALD), electroless deposition (ELD), electrochemical plating (ECP) or other suitable processes. In addition, the barrier layer 105 may include silicon oxycarbide, silicon carbonitride, silicon nitride, silicon oxycarbide, silicon oxide, silicon carbide, silicon oxynitride or other suitable dielectric materials. The barrier layer 105 may be formed by chemical vapor deposition (CVD), physical vapor deposition (PVD), atomic layer deposition (ALD), or other suitable processes. The barrier layer 105 may be formed between the first dielectric layer 102 and the second conductive material 106 and between the second dielectric layer 102′ and the second conductive material 106, the barrier layer 105 can prevent diffusion of the second conductive material 106 (such as Copper) into the dielectric materials.

In one embodiment, the first conductive material 103 has a higher melting point and higher tensile strength than the second conductive material 106. Due to the rapid diffusion of copper atoms, under the acceleration of the electric field, copper atoms can penetrate the dielectric layer and diffuse rapidly, especially for silicon substrates. Once copper atoms diffuse into the dielectric layer, it will cause deep energy level traps and cause component characteristic degradation and failure. Therefore, a diffusion barrier layer 105 must be deposited between the copper wire and the dielectric layer. However, the resistivity of the barrier layer 105 is high (about 50˜150 μΩ-cm), which increases the resistance value of the overall wire. Since the melting point of the material itself is inversely proportional to the diffusivity, the higher the melting point is, the lower the diffusivity is. Therefore, a metal or alloy with a high melting point is selected as the first conductive material 103 to replace copper or copper alloy with a low melting point. In addition, the first conductive material 103 with a high melting point can be directly deposited in the blind via or the trench without the barrier layer 105, so that the resistance value of the interconnection structure 100 can be greatly improved.

Generally speaking, the resistivity of the copper wire is 1.67 μΩ-cm, but in fact, the resistivity of the deposited copper film will increase slightly due to the existence of defects. The main defects that affect resistivity are surface state and grain boundary scattering, both of which are related to the mean free path of electrons, film thickness, and grain size. Especially when the line width of the copper wire is less than 10 nm, the resistivity of the copper wire increases significantly. Please refer to the detail description of the following embodiments.

In addition, in FIG. 1B, the interconnection structure 100 may include a third conductive feature 110 including a third conductive material 108 and a barrier layer 109. The third conductive material 108 includes copper or copper alloy. The third conductive material 108 is formed, for example, by chemical vapor deposition (CVD), atomic layer deposition (ALD), electroless deposition (ELD), electrochemical plating (ECP) or other suitable processes. The third conductive material 108 can be the same as or different from the second conductive material 106, and the second conductive feature 107 and the third conductive feature 110 can be formed simultaneously in the same deposition process or independently formed.

In some embodiments, the first conductive feature 104 and the second conductive feature 107 are embedded in the first dielectric layer 102 and the second dielectric layer 102′, respectively, to form a dual damascene structure. The third conductive feature 110 is embedded in the first dielectric layer 102 and the second dielectric layer 102′ to form a dual damascene structure.

In some embodiments, barrier layers 105, 109 may be formed between the first dielectric layer 102 and the second/third conductive materials 106 and 108 and between the second dielectric layer 102′ and the second/third conductive materials 106 and 108. Taking the dual damascene process as an example, the etch stop layer (ESL) 111, the first dielectric layer 102 and the second dielectric layer 102′ are sequentially deposited and etched to form blind vias and trenches of predetermined patterns. In some embodiments, the blind vias and trenches of predetermined patterns can be formed by dry etching, wet etching or other suitable processes. In addition, the etch stop layer 111 may include SiON, SiOx, SiOxCy, AlOx, SiNx, TIN, AlN, WC or other suitable materials, which can be deposited by chemical vapor deposition (CVD), physical vapor deposition (PVD), atomic layer deposition (ALD) or other suitable processes.

Then, the barrier layers 105, 109 are deposited in the blind vias and trenches, and a conductive material (for example, copper) is deposited on the respective barrier layers 105, 109. Depositing the conductive material on the barrier layers 105 and 109 may include forming a seed layer on the barrier layer 105 through a physical vapor deposition (PVD) process, and then forming the conductive material on the seed layer through an electrodeposition process. Thereafter, the upper surface of the conductive material is planarized such that the upper surfaces of the second conductive feature 107 and the third conductive feature 110 and the upper surface of the second dielectric layer 102′ are substantially coplanar.

In some embodiments, the resistivity of the second conductive material 106 is greater than the resistivity of the first conductive material 103. According to Ohm's law, resistivity is defined as ρ=E/J, the ratio of electric field to current density, E represents the magnitude of the electric field, and J represents the magnitude of the current density, so p is the resistivity of the material. In terms of units, the unit of E is volts/meter, and the unit of J is ampere/square meter, so the unit of p is volt-meter/ampere.

For a cuboid uniform metal whose length is L and whose cross-sectional area is A, the resistivity is ρ=R*A/L, where R is the resistance of the metal. This formula can also be called the law of resistance, which means that when the metal material is fixed, the resistance is proportional to the length and inversely proportional to the area. In terms of units, the unit of R is ohm, the unit of A is square meter, and the unit of L is meter, so the unit of resistivity p is ohm-meter. However, the resistivity changes with the decrease of the width of metal line, especially when the line width is below 100 nm, the resistivity of the metal line tends to increase significantly.

Taking a copper wire as an example, the electron scattering due to the surface and grain boundaries of the copper film will cause the resistivity of the copper film to be significantly higher than that of the corresponding copper block. Similar to copper thin films, the resistivity of copper wires also exhibits a significant size effect when the width of the copper wires is in the order of magnitude of the mean free path of free electrons (usually below 100 nm). Experiments have found that the resistivity of the copper wire decreases significantly with the increase of the line width (80-500 nm), and when the line width is greater than 500 nm, the resistivity of the copper wire remains basically unchanged. When the line width is between 10 nm and 80 nm, the resistivity tends to increase significantly with the decrease of the width of the copper wire. When the width of the copper wire is reduced to about 10 nm, the conductivity shows a dramatically decline trend, indicating that the critical dimension (such as line width) plays a leading role in determining the resistivity of the copper wire at this time.

Therefore, when the width of the copper wire or the diameter of the copper conductive via is reduced to about 10 nm, the resistivity of the copper wire or the conductive via tends to increase significantly, and is no longer suitable as the material for the interconnection structure 100. Therefore, other suitable conductive materials need to be selected to replace copper wires or copper conductive vias. In one embodiment, the first conductive material 103 can be alternative materials that do not contain copper, the alternative material can be metals or alloys, such as W, Co, Ni, Al, Rh, Ir, Ru, Mo, Ag, Au, NiAl, RuAl, VNi, VPt, AlSc or the combination of the metals or alloys above with different composition, which have lower resistances compared to conventional copper interconnection structure and have lower power consumptions compared to copper interconnection structure due to lower resistivity. Therefore, the alternative material can be utilized in BEOL interconnection structure and can act as a conductor to provide benefit of lower resistance and higher performance.

In one embodiment, the first conductive feature 104 has a first critical dimension A1 and the second conductive feature 107 has a second critical dimension A2. The first critical dimension A1 is smaller than the second critical dimension A2. The first critical dimension A1 and the second critical dimension A2 are, for example, line widths or via diameters. When the first critical dimension A1 and the second critical dimension A2 are less than 100 nm, such as about 10 nm, the resistivity tends to increase significantly as the critical dimension (the line width or the via diameter) decreases, so that an alternative material with smaller resistivity scaling than Cu is selected as the first conductive material 103 and can be integrated into BEOL without using the barrier layer 105. Therefore, narrow wires or smaller vias using alternative metals can have lower resistance than using copper. In sum, this aims to solve the issue of localized high resistance in BEOL interconnection structure by replacing copper with other metals.

Furthermore, in one embodiment, the third conductive feature 110 has a third critical dimension A3, wherein the third critical dimension A3 is greater than the first critical dimension A1. The third critical dimension A3 is, for example, greater than 10 nm. When the third critical dimension A3 is greater than 10 nm, the resistivity tends to decrease with the increase of the critical dimension (such as line width or via diameter), so there is no need to choose an alternative material with smaller resistivity scaling than Cu as the third conductive material 108.

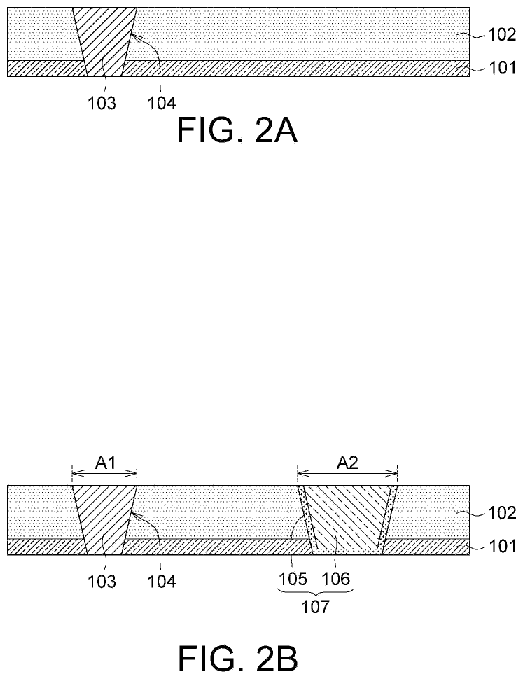

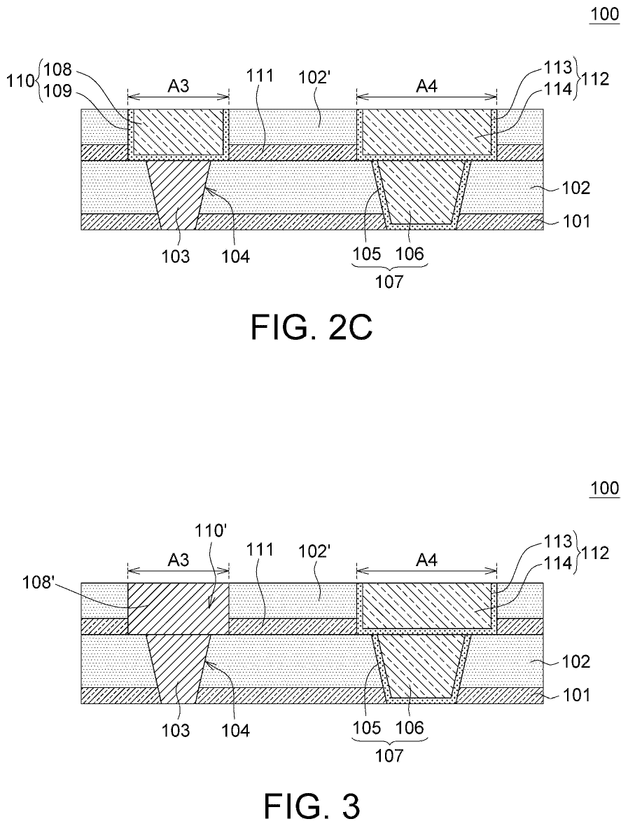

Referring to FIGS. 2A to 2C, a flow chart of an exemplary manufacturing method of the interconnection structure 100 according to another embodiment of the present disclosure is shown. First, in FIG. 2A, a first dielectric layer 102 is formed on a first etch stop layer 111. Next, the first dielectric layer 102 is patterned to form a predetermined pattern (such as a blind via), and fill the first conductive material 103 in the blind via to form a first conductive feature 104, which is similar to FIG. 1A. Next, in FIG. 2B, the first dielectric layer 102 is patterned to form a predetermined pattern (such as a blind via), and a barrier layer 105 and a second conductive material 106 are filled in the blind via to form a second conductive feature 107.

In this embodiment, the first conductive feature 104 includes a first conductive material 103, the second conductive feature 107 includes a second conductive material 106 and a barrier layer 105, and the first conductive material 103 is different from the second conductive material 106 and they are formed in the first dielectric layer 102 using a respective deposition process. In one embodiment, the first conductive material 103 may be alternative materials that do not contain copper, and the second conductive material 106 may contain copper or a copper alloy. The alternative materials other than copper have been described in the above embodiments, and will not be repeated here. In addition, the first conductive material 103 is, for example, a higher melting point conductive metal than copper, and there is no need to form the barrier layer 105 in the first conductive feature 104.

Next, in FIG. 2C, a second dielectric layer 102′ is formed on top of the first dielectric layer 102, and there is a second etch stop layer 111 between the first dielectric layer 102 and the second dielectric layer 102′. Next, the second dielectric layer 102′ is patterned to form a predetermined pattern (such as a trench), and a barrier layer 109 and a third conductive material 108 are filled in the trench to form a third conductive feature 110. In addition, the fourth conductive feature 112 may be formed in the second dielectric layer 102′ by the same process. The third conductive material 108 may be the same as or different from the second conductive material 106, and the third conductive material 108 may include copper or a copper alloy.

In some embodiments, the first conductive feature 104 and the second conductive feature 107 are respectively embedded in the first dielectric layer 102 and are not connected to each other. Additionally, the third conductive feature 110 is connected to the first conductive feature 104 to form a dual damascene structure. The fourth conductive feature 112 is connected to the second conductive feature 107 to form a dual damascene structure.

In some embodiments, the resistivity of the second conductive material 106 is greater than the resistivity of the first conductive material 103. As described in the above embodiments, the resistivity changes with the decrease of the critical dimension (such as the line width or the via diameter), especially when the critical dimension is below 100 nm (such as below about 10 nm), the resistivity of the copper wire has an increasing trend. Therefore, the suitable conductive materials need to be selected to replace copper wires or copper conductive vias.

In one embodiment, the first conductive feature 104 has a first critical dimension A1 and the second conductive feature 107 has a second critical dimension A2. The first critical dimension A1 is smaller than the second critical dimension Size A2. The first critical dimension A1 is, for example, smaller than 10 nm, and the second critical dimension A2 is, for example, greater than 10 nm. In addition, the third conductive feature 110 has a third critical dimension A3, and the fourth conductive feature 112 has a fourth critical dimension A4. The third critical dimension A3 and the fourth critical dimension A4 are greater than the first critical dimension A1. The third critical dimension A3 and the fourth critical dimension A4 are, for example, greater than 10 nm and less than 100 nm. When the third critical dimension A3 is greater than 10 nm, the resistivity tends to decrease with the increase of the critical dimension (such as line width or via diameter), so there is no need to choose an alternative with smaller resistivity scaling than Cu as the third conductive material 108.

Referring to FIG. 3, a schematic diagram of an interconnection structure 100 according to another embodiment of the present disclosure is shown. Compared to FIG. 2C, the difference is that the third conductive feature 110′ and the fourth conductive feature 112 of this embodiment are formed of different materials, the third conductive feature 110 includes a third conductive material 108′, and the conductive feature 112 includes a fourth conductive material 114 and a barrier layer 113. The third conductive material 108′ can be the same as or different from the first conductive material 103. The third conductive material 108′ can be alternative materials that do not contain copper, and the alternative materials other than copper have been described in the above-mentioned embodiments, and will not be repeated here. In addition, the third conductive material 108′ is, for example, a material with a higher melting point than copper, and there is no need to form the barrier layer 113 in the third conductive feature 110′.

In one embodiment, the second dielectric layer 102′ is patterned to form a predetermined pattern (such as a trench), and a third conductive material 108′ is filled in the trench to form a third conductive feature 110′. The third conductive feature 110′ (such as a wire) is electrically connected to the first conductive feature 104 (such as a conductive via) to form a dual damascene structure. In one embodiment, the first conductive feature 104 has a first critical dimension A1 (e.g., via diameter), and the third conductive feature 110′ has a third critical dimension A3 (e.g., line width). The first critical dimension A1 is smaller than or equal to the third critical dimension A3. In one embodiment, the first critical dimension A1 and the third critical dimension A3 are, for example, smaller than 10 nm.

In one embodiment, the third conductive feature 110′ has a third critical dimension A3 (e.g., line width), the fourth conductive feature 112 has a fourth critical dimension A4 (e.g., line width), and the fourth critical dimension A4 is greater than the third critical dimension A3. In an embodiment, the third critical dimension A3 is, for example, smaller than 10 nm, and the fourth critical dimension A4 is, for example, greater than 10 nm.

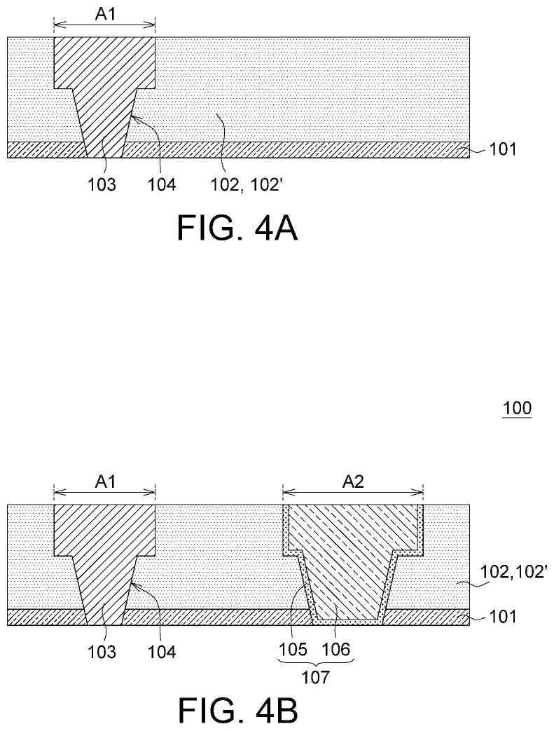

Referring to FIG. 4A and FIG. 4B, a flow chart of an exemplary manufacturing method of the interconnection structure 100 according to another embodiment of the present disclosure is shown. Compared to FIG. 3, the difference is that the conductive vias and wires of the first conductive feature 104 in this embodiment are formed with the same process and the same material, and the conductive vias and wires of the second conductive feature 107 are formed with the same process and the same material. The first conductive feature 104 and the second conductive feature 107 are respectively embedded in the first dielectric layer 102 and the second dielectric layer 102′ and are electrically insulated from each other, and there is no need to form an etch stop layer 111 between the first dielectric layer 102 and the second dielectric layer 102′.

In one embodiment, the etch stop layer 111, the first dielectric layer 102 and the second dielectric layer 102′ are sequentially deposited and etched to form blind vias and trenches of predetermined patterns in the first dielectric layer 102 and the second dielectric layer 102′. Then, a first conductive material 103 is deposited in the blind vias and the trenches to form the first conductive features 104 (such as a conductive vias and a line) of the dual damascene structure. Next, blind vias and trenches of a predetermined pattern are formed in the first dielectric layer 102 and the second dielectric layer 102′. Then, a barrier layer 105 and a second conductive material 106 are deposited in another blind via and another trench to form a second conductive feature 107 (such as a conductive via and a line) of the dual damascene structure.

In one embodiment, the first conductive feature 104 has a first critical dimension A1 (e.g. line width), the second conductive feature 107 has a second critical dimension A2 (e.g. line width), and the second critical dimension A2 is greater than the first critical dimension A1. In one embodiment, the first critical dimension A1 is, for example, smaller than 10 nm, and the second critical dimension A2 is, for example, greater than 10 nm.

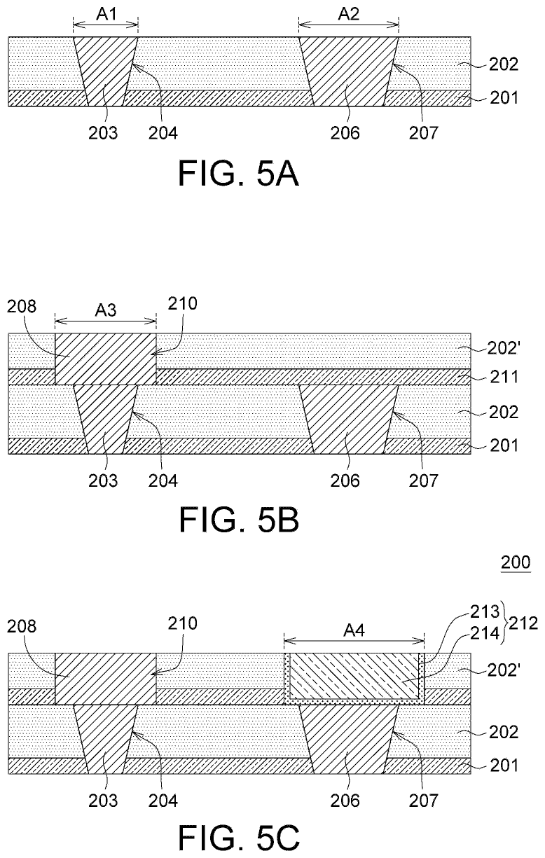

Referring to FIG. 5A to FIG. 5C, a flow chart of an exemplary manufacturing method of the interconnection structure 200 according to another embodiment of the present disclosure is shown. Compared to FIGS. 2A to 2C, the difference is that in FIG. 5A, the first dielectric layer 202 is formed on an etch stop layer 201, and the first dielectric layer 202 is patterned to form a predetermined pattern (such as blind via), and the first conductive material 203 and the second conductive material 206 are filled in the blind vias to form a first conductive feature 204 and a second conductive feature 207. The first conductive feature 204 and the second conductive feature 207 are formed by the same process and the same material, for example, the first conductive feature 204 has a first critical dimension A1, and the second conductive feature 207 has a second critical dimension A2. The second critical dimension A2 is greater than the first critical dimension A1. In one embodiment, the first critical dimension A1 is, for example, smaller than 10 nm, and the second critical dimension A2 is, for example, greater than 10 nm. In one embodiment, the first conductive feature 204 includes a first conductive material 203, the second conductive feature 207 includes a second conductive material 206, and the first conductive material 203 can be the same with the second conductive material 206, and the first conductive material 203 and the second conductive material 206 do not contain copper or copper alloy. Since the first conductive feature 204 and the second conductive feature 207 do not contain a highly diffusible metal (such as copper), and contain a metal with a higher melting point than copper, there is no need to form a barrier layer in the first conductive feature 204 and the second conductive feature 207.

Next, in FIG. 5B, a second dielectric layer 202′ is formed on top of the first dielectric layer 202, and there is a second etch stop layer 211 between the first dielectric layer 202 and the second dielectric layer 202′. Next, the second dielectric layer 202′ is patterned to form a predetermined pattern (such as a trench), and a third conductive material 208 is filled in the trench to form a third conductive feature 210. The third conductive material 208 can be the same as or different from the first conductive material 203. The first conductive material 203 and the third conductive material 208 can be alternative materials that do not contain copper. The alternative materials other than copper have been described in the above-mentioned embodiments, description and will not be repeated here. In addition, the third conductive material 208 is, for example, a metal with a higher melting point than copper, and there is no need to form a barrier layer in the third conductive feature 210.

Next, in FIG. 5C, the second dielectric layer 202′ is patterned to form a predetermined pattern (such as a trench), and a barrier layer 213 and a fourth conductive material 214 are filled in the trench to form a fourth conductive feature 212. The fourth conductive material 214 may be different from the third conductive material 208 and the fourth conductive material 214 may include copper or copper alloy. The first to fourth critical dimensions A1 to A4 of the first to fourth conductive features 204, 207, 210, 212 have been similarly described in the above embodiments, and will not be repeated here.

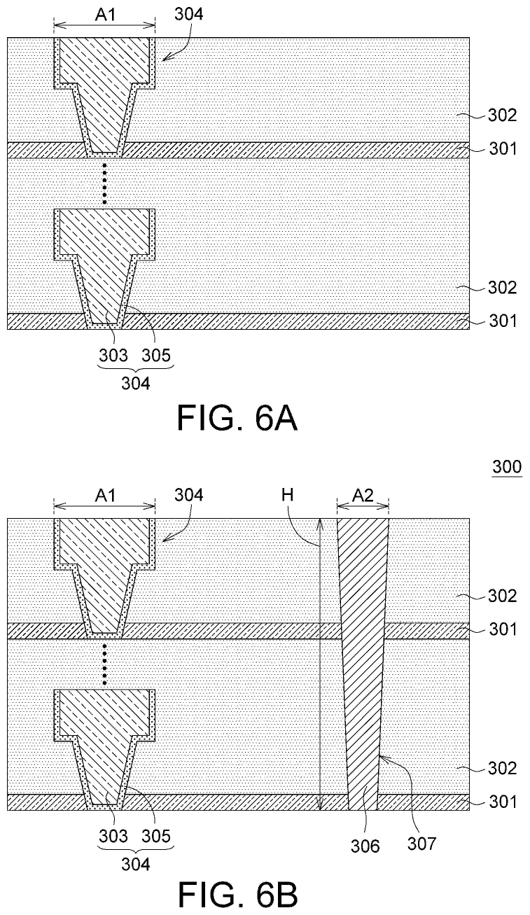

Referring to FIG. 6A and FIG. 6B, a flowchart of an exemplary manufacturing method of the interconnection structure 300 according to another embodiment of the present disclosure is shown. First, in FIG. 6A, a dielectric layer 302 is formed on an etch stop layer 301. Next, the dielectric layer 302 is patterned to form a predetermined pattern (such as blind vias and trenches), and a barrier layer 305 and a first conductive material 103 are filled in the blind vias and trenches to form a first conductive feature 304 (e.g., conductive vias and lines). Next, repeat the above steps at least once to form a plurality of dielectric layers 302 on the respective etching stop layers 301, and correspondingly form a plurality of first conductive features 304 stacked in the dielectric layers 302, the number can be 2 to 10. The first conductive features 304 are stacked and electrically connected to form an interconnection structure 300.

In one embodiment, first conductive feature 304 may include copper or copper alloy. The first conductive feature 304 has a first critical dimension A1 (e.g., line width or via diameter), where the first critical dimension A1 is, for example, greater than 10 nm.

Next, in FIG. 6B, a plurality of dielectric layers 302 are patterned to form a predetermined pattern (such as a blind via with a high aspect ratio), and a second conductive material 306 is filled in the blind via with a high aspect ratio to form a second conductive feature 307 (such as a conductive via). In one embodiment, the second conductive feature 307 may be an alternative material that does not include copper. The alternative materials other than copper have been described in the above embodiments, and will not be repeated here. In addition, the second conductive material 306 is, for example, a metal with a higher melting point than copper, and there is no need to form a barrier layer in the second conductive feature 307.

In one embodiment, the resistivity of the first conductive material 303 is greater than the resistivity of the second conductive material 306. In addition, the second conductive feature 307 has a second critical dimension A2 (e.g., via diameter), and the second critical dimension A2 is smaller than the first critical dimension A1. The first critical dimension A1 is, for example, greater than 10 nm, and the second critical dimension A2 is, for example, smaller than 10 nm. When the second critical dimension A2 is less than 100 nm, such as about 10 nm, the resistivity tends to increase significantly as the critical dimension (line width or via diameter) decreases, so that an alternative material with smaller resistivity scaling than copper is selected as the second conductive material 306. In addition, the height H of the second conductive feature 307 is substantially equal to the sum of the heights of the first conductive features 304 to form a conductive via with a high aspect ratio H/A2 (e.g., greater than 10 or 20).

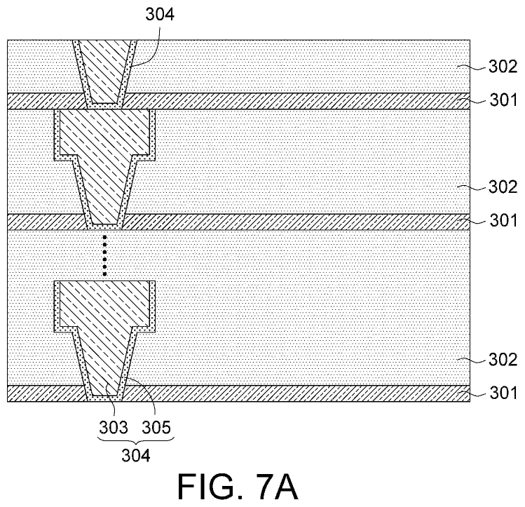

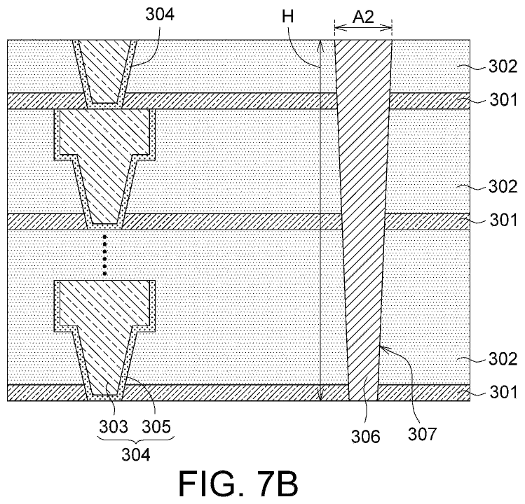

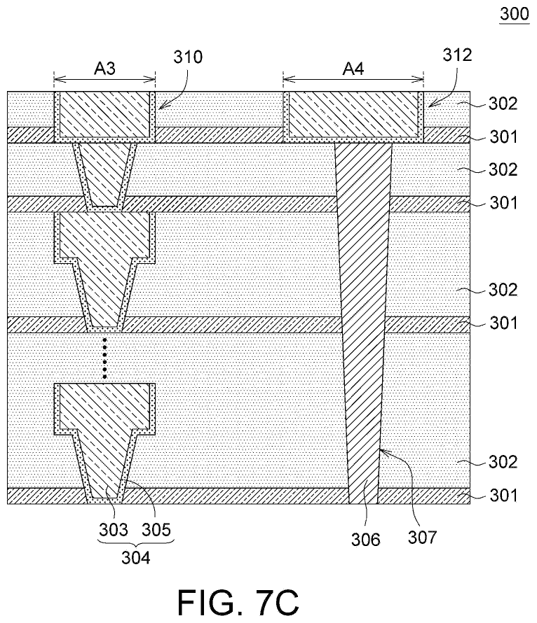

Referring to FIGS. 7A to 7C, a flowchart of an exemplary manufacturing method of an interconnection structure 300 according to another embodiment of the present disclosure is shown. The manufacturing method of the interconnection structure 300 of this embodiment is generally similar to FIG. 6A and FIG. 6B. The difference is that in FIG. 6B, the top surface of the second conductive feature 307 and the top surfaces of the lines of the uppermost first conductive feature 304 are coplanar. In FIG. 7B, the top surface of the second conductive feature 307 and the top surface of the via of the uppermost first conductive feature 304 are coplanar. The manufacturing method of the uppermost first conductive feature 304 is similar to that of the second conductive feature 107 in FIG. 2B, and will not be repeated here.

In addition, in FIG. 7C, a third conductive feature 310 and a fourth conductive feature 312 are formed in the uppermost dielectric layer 302. The third conductive feature 310 can be electrically connected with the uppermost first conductive feature 312. Additionally, the fourth conductive feature 312 is electrically connected to the second conductive feature 307 of high aspect ratio. The manufacturing method of the third conductive feature 310 and the fourth conductive feature 312 is similar to the third conductive feature 110 and the fourth conductive feature 112 of FIG. 2C, and will not be repeated here.

In one embodiment, the fourth conductive feature 312 has a fourth critical dimension A4 (e.g., line width), and the fourth critical dimension A4 is greater than the third critical dimension A3. The third critical dimension A3 and the fourth critical dimension A4 are, for example, greater than 10 nm. When the fourth critical dimension A4 is greater than 10 nm, the resistivity tends to decrease as the critical dimension (such as line width or via diameter) increases, so there is no need to choose an alternative with smaller resistivity scaling than Cu as the conductive material of the fourth conductive feature 312.

The present disclosure is directed to improve BEOL interconnect performance by integrating alternative metals other than Copper. These alternative metals can be implanted into BEOLs and provide lower resistivity than copper when the critical dimensions of the alternative metals are small enough. In one embodiment, compared to the commonly used conductive material copper (Cu), the alternative metals such as molybdenum (Mo) and tungsten (W) have lower resistivity than Cu because the mean free path (MFP) of the alternative metals is smaller than that of Cu, which helps reduce electron scattering at grain boundaries, thereby improving electrical properties. Therefore, using alternative metals other than copper with narrow wires or smaller vias can have lower resistance than using copper, thus solving the problem of localized high resistance in BEOL copper interconnection structures.

According to some embodiments of the disclosure, an interconnection structure including a first dielectric layer, a second dielectric layer, a first conductive feature, and a second conductive feature is provided. The second dielectric layer is disposed on one side of the first dielectric layer. The first conductive feature is embedded in at least one of the first dielectric layer and the second dielectric layer, the second conductive feature is embedded in at least one of the first dielectric layer and the second dielectric layer. The first The conductive feature includes a first conductive material, the second conductive feature includes a second conductive material and a barrier layer, and the first conductive material is different from the second conductive material. The first conductive material does not contain copper, and the second conductive material contains copper.

According to some embodiments of the disclosure, an interconnection structure including a first dielectric layer, a second dielectric layer, a first conductive feature, and a second conductive feature is provided. The second dielectric layer is disposed on one side of the first dielectric layer, the first conductive feature is embedded in the first dielectric layer, and a second conductive feature is embedded in the first dielectric layer. The first conductive feature has a first critical dimension, the second conductive feature has a second critical dimension, and the second critical dimension is greater than the first critical dimension.

According to some embodiments of the disclosure, an interconnection structure including a plurality of dielectric layers, a plurality of first conductive features, and a second conductive feature is provided. The plurality of first conductive features is stacked in the dielectric layers. The second conductive feature is embedded in the dielectric layers, the first conductive features comprises a first conductive material, the third conductive feature comprises a second conductive material, the first conductive material and the second conductive material are different, and the first conductive material contains copper, and the second conductive material does not contain copper.

According to some embodiments of the disclosure, a method for manufacturing an interconnection structure is provided. A first dielectric layer is formed on a first etch stop layer. A first conductive feature is formed in the first dielectric layer. A second dielectric layer is disposed on one side of the first dielectric layer. A second conductive feature is formed in at least one of the first and second dielectric layers. The first conductive features comprises a first conductive material, the second conductive feature comprises a second conductive material, the first conductive material and the second conductive material are different, and the first conductive material contains copper, and the second conductive material does not contain copper.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An interconnection structure, comprising:
a first dielectric layer;
a second dielectric layer disposed on one side of the first dielectric layer;
a first conductive feature embedded in at least one of the first dielectric layer and the second dielectric layer; and
a second conductive feature embedded in at least one of the first dielectric layer and the second dielectric layer, wherein the first conductive feature comprises a first conductive material and the second conductive feature comprises a second conductive material and a barrier layer, the first conductive material is different from the second conductive material, and the first conductive material does not contain copper, and the second conductive material contains copper.

2. The interconnection structure according to claim 1, wherein a resistivity of the second conductive material is greater than a resistivity of the first conductive material.

3. The interconnection structure according to claim 1, wherein the first conductive feature and the second conductive feature are respectively embedded in the first dielectric layer and the second dielectric layer and are electrically connected to each other.

4. The interconnection structure according to claim 1, wherein the first conductive feature and the second conductive feature are respectively embedded in the first dielectric layer and are not connected to each other.

5. The interconnection structure according to claim 1, wherein a melting point of the first conductive material is higher than a melting point of the second conductive material.

6. The interconnection structure according to claim 4, further comprising a third conductive feature and a fourth conductive feature respectively formed in the second dielectric layer, wherein the third conductive feature and the first conductive feature is electrically connected, and the fourth conductive feature is electrically connected to the second conductive feature.

7. The interconnection structure according to claim 6, wherein the third conductive feature comprises a third conductive material, the fourth conductive feature comprises a fourth conductive material, the third conductive material and the fourth conductive material are different, the third conductive material does not contain copper, and the fourth conductive material contain copper.

8. The interconnection structure according to claim 7, wherein the third conductive feature has a third critical dimension, the fourth conductive feature has a fourth critical dimension, and the fourth critical dimension is greater than the third critical dimension.

9. The interconnection structure according to claim 6, wherein the first conductive feature has a first critical dimension, the second conductive feature has a second critical dimension, and the second critical dimension is greater than the first critical dimension.

10. The interconnection structure according to claim 9, wherein the first conductive material comprises cobalt (Co), ruthenium (Ru), molybdenum (Mo), chromium (Cr), tungsten (W), manganese (Mn), Rhodium (Rh), iridium (Ir), nickel (Ni), palladium (Pd), platinum (Pt), silver (Ag), gold (Au), aluminum (A1) or alloys of the above metals.

11. The interconnection structure according to claim 9, wherein the first conductive material includes NiAl, RuAl, VNi, VPt, AlSc or a combination of the above alloys.

12. An interconnection structure, comprising:
a first dielectric layer;
a second dielectric layer disposed on one side of the first dielectric layer;
a first conductive feature embedded in the first dielectric layer; and
a second conductive feature embedded in the first dielectric layer, wherein the first conductive feature has a first critical dimension, the second conductive feature has a second critical dimension, and the second critical dimension is greater than the first critical dimension.

13. The interconnection structure according to claim 12, wherein the first conductive feature comprises a first conductive material, the second conductive feature comprises a second conductive material, and the first conductive material and the second conductive material are the same, and the first conductive material and the second conductive material do not contain copper.

14. The interconnection structure according to claim 12, further comprises a third conductive feature and a fourth conductive feature respectively formed in the second dielectric layer, the third conductive feature and the first conductive feature are electrically connected, and the fourth conductive feature and the second conductive feature are electrically connected.

15. The interconnection structure according to claim 14, wherein the third conductive feature comprises a third conductive material, the fourth conductive feature comprises a fourth conductive material, and the third conductive material and the fourth conductive material are different, and the third conductive material does not contain copper, the fourth conductive material contains copper.

16. The interconnection structure according to claim 15, wherein the third conductive feature has a third critical dimension, the fourth conductive feature has a fourth critical dimension, and the fourth critical dimension is greater than the third critical dimension.

17. A method for manufacturing an interconnection structure comprising:
forming a first dielectric layer formed on a first etch stop layer;
forming a first conductive feature in the first dielectric layer;
disposing a second dielectric layer on one side of the first dielectric layer to cover the first conductive feature; and
forming a second conductive feature in at least one of the first dielectric layer and the second dielectric layer,
wherein the first conductive feature comprises a first conductive material and the second conductive feature comprises a second conductive material and a barrier layer, the first conductive material is different from the second conductive material, and the first conductive material does not contain copper, and the second conductive material contains copper.

18. The method according to claim 17, further comprising forming a third conductive feature in the first and second dielectric layers, wherein the third conductive feature comprises a third conductive material, the third conductive material does not contain copper.

19. The method according to claim 17, further comprising forming a third conductive feature and a fourth conductive feature respectively in the second dielectric layer, wherein the third conductive feature and the first conductive feature is electrically connected, and the fourth conductive feature is electrically connected to the second conductive feature.

20. The interconnection structure according to claim 19, wherein the third conductive feature comprises a third conductive material, the fourth conductive feature comprises a fourth conductive material, and the third conductive material and the fourth conductive material are different, and the third conductive material does not contain copper, the fourth conductive material contains copper.
